(19) United States
(12) Patent Application Publication
(10) Pub. No.: US 2026/0255813 A1
(43) Pub. Date: Aug. 27, 2026

(54) DISPLAY SUBSTRATE AND MANUFACTURING METHOD THEREFOR, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Peng HUANG, Beijing (CN); Tao GAO, Beijing (CN); Bingqiang GUI, Beijing (CN); Zhendong LI, Beijing (CN)

(21) Appl. No.: 18/726,415

(22) PCT Filed: May 29, 2023
(86) PCT No.: PCT/CN2023/096926

§ 371 Date: Jul. 3, 2024

(30) Foreign Application Priority Data
Jun. 17, 2022 (CN) 202210693342.0

(51) Int. Cl. H10K 59/131; H10K 59/12

(52) U.S. Cl. CPC H10K 59/131; H10K 59/1201

(57) ABSTRACT

A display substrate and a manufacturing method therefor, and a display device. The display substrate comprises a display region (100), and a bonding region (200), which is located at a side of the display region, wherein the bonding region comprises a lead area (210), a first transition area (220), a bending area (230), a second transition area (240) and a bonding pin area (250), which are sequentially arranged in a direction away from the display region; on a plane perpendicular to the display substrate, the lead area and the bonding pin area comprise a composite insulating layer, which is arranged on a substrate body, and a metal line, which is arranged on the side of the composite insulating layer away from the substrate body; the first transition area and the second transition area comprise the composite insulating layer, an inorganic insulating layer (14) and a metal line (15).

### CROSS-REFERENCE TO RELATED APPLICATION

The present application is a U.S. National Phase Entry of International Application No. PCT/CN2023/096926 having an international filing date of May 29, 2023, which claims priority to Chinese Patent Application No. 202210693342.0 filed to the CNIPA on Jun. 17, 2022 and entitled “Display Substrate and Manufacturing Method Therefor, and Display Device”. Contents of the above-identified applications are incorporated into the present application by reference.

### TECHNICAL FIELD

Embodiments of the present disclosure relate to, but are not limited to, the field of display technologies, and particularly relates to a display substrate, a manufacturing method of the display substrate, and a display apparatus.

### BACKGROUND

An organic light emitting diode (OLED) and a quantum dot light emitting diode (QLED) are active light emitting display devices, which have advantages such as self-luminescence, wide viewing angle, high contrast ratio, low power consumption, a very high response speed, lightness and thinness, bendability, and a low cost. With the continuous development of display technologies, a flexible display apparatus (Flexible Display) in which an OLED or a QLED is used as a light emitting device and signal control is performed through a thin film transistor (TFT) has become a mainstream product in the field of display at present.

### SUMMARY

The following is a summary of subject matter described herein in detail. This summary is not intended to limit the protection scope of the claims.

An embodiment of the present disclosure provides a display substrate, including a display area and a bonding area located on a side of the display area. The bonding area includes a lead region, a first transition region, a bending region, a second transition region, and a bonding pin region sequentially provided in a direction away from the display area. In a plane perpendicular to the display substrate, the lead region and the bonding pin region include a composite insulation layer provided on a base substrate and a metal line provided on a side of the composite insulation layer away from the base substrate, and the first transition region and the second transition region include a composite insulation layer provided on the base substrate, an inorganic insulation layer provided on a side of the composite insulation layer away from the base substrate, and a metal line provided on a side of the inorganic insulation layer away from the base substrate. The bonding area is further provided with a structure hole for maintaining photoresist thickness of the first transition region and the second transition region.

In an exemplary implementation, at least one structure hole is provided in at least one or more of the lead region, the first transition region, the second transition region, and the bonding pin region and the structure hole is provided in the metal line.

In an exemplary implementation, the structural hole includes a first structure hole and the first structure hole is provided at any one or more of the following positions: the lead region and the first transition region.

In an exemplary implementation, the first structure hole of the lead region is provided in an area of the lead region close to the first transition region and the first structure hole of the first transition region is provided in an area of the first transition region close to the lead region.

In an exemplary implementation, the first transition region includes a first climbing region and a first planarization region, the first climbing region is located on a side of the first transition region close to the lead region, the first planarization region is located on a side of the first climbing region away from the lead region, and the first structure hole is provided in a metal line of the first planarization region.

In an exemplary implementation, the structure hole includes a second structure hole and the second structure hole is provided at any one or more of the following positions: the bonding pin region and the second transition region.

In an exemplary implementation, the second structure hole of the bonding pin region is provided in an area of the bonding pin region close to the second transition region and the second structure hole of the second transition region is provided in an area of the second transition region close to the bonding pin region.

In an exemplary implementation, the second transition region includes a second climbing region and a second planarization region, the second climbing region is located on a side of the second transition region close to the bonding pin region, the second planarization region is located on a side of the second climbing region away from the bonding pin region, and the second structure hole is provided in a metal line of the second planarization region.

In an exemplary implementation, at least one structure hole is provided in at least one or more of the first transition region and the second transition region and the structure hole is provided in the inorganic insulation layer.

In an exemplary implementation, the structure hole includes a third structure hole and a fourth structure hole, the third structure hole is provided in the first transition region, and the fourth structure hole is provided in the second transition region.

In an exemplary implementation, the third structure hole is provided in an area of the first transition region close to the lead region and the fourth structure hole is provided in an area of the second transition region close to the bonding pin region.

In an exemplary implementation, the metal line covers a hole wall and a hole bottom of the third structure hole and the metal line covers a hole wall and a hole bottom of the fourth structure hole.

In an exemplary implementation, a shape of the structure hole includes any one or more of the following: a triangle, a rectangle, a pentagon, a hexagon, a circle, and an ellipse.

In an exemplary implementation, the structure hole has a circular shape, a diameter of the structure hole is greater than or equal to ¼ of a width of the metal line, the diameter of the structure hole is less than or equal to ⅔ of the width of the metal line, and the width of the metal line is a dimension perpendicular to an extension direction of the metal line.

In an exemplary implementation, multiple structure holes have the same area.

In an exemplary implementation, an area of the multiple structure holes is gradually increased in the direction away from the display area, or an area of the multiple structure holes is gradually increased in a direction close to the display area.

In an exemplary implementation, an area of the multiple structure holes in the lead region is gradually increased in a direction away from the first transition region; an area of the multiple structure holes in the first transition region is gradually increased in a direction away from the lead region; an area of the multiple structure holes in the second transition region is gradually increased in a direction away from the bonding pin region; and an area of the multiple structure holes in the bonding pin region is gradually increased in a direction away from the second transition region.

An embodiment of the present disclosure further provides a display apparatus which includes the display substrate in any one of above embodiments.

An embodiment of the present disclosure further provides a manufacturing method of a display substrate, the display substrate includes a display area and a bonding area located on a side of the display area, and the bonding area includes a lead region, a first transition region, a bending region, a second transition region, and a bonding pin region sequentially provided in a direction away from the display area.

The manufacturing method includes: forming a composite insulation layer provided on a base substrate and a metal line provided on a side of the composite insulation layer away from the base substrate in the lead region and the bonding pin region; forming a composite insulation layer provided on the base substrate, an inorganic insulation layer provided on a side of the composite insulation layer away from the base substrate, and a metal line provided on a side of the inorganic insulation layer away from the base substrate in the first transition region and the second transition region; and forming a structure hole for maintaining photoresist thicknesses of the first transition region and the second transition region in the bonding area.

Other aspects of the present disclosure may be comprehended after the drawings and the detailed descriptions are read and understood.

### BRIEF DESCRIPTION OF DRAWINGS

Accompanying drawings are intended to provide further understanding of technical solutions of the present disclosure and form a part of the specification, and are used to explain the technical solutions of the present disclosure together with embodiments of the present disclosure, but do not constitute a limitation on the technical solutions of the present disclosure. Shapes and sizes of components in the drawings do not reflect actual scales, and are only intended to schematically illustrate contents of the present disclosure.

FIG. 1 is a schematic diagram of a structure of a display apparatus.

FIG. 2 is a schematic diagram of a planar structure of a display substrate.

FIG. 3 is a side view of the display substrate in FIG. 2.

FIG. 4 is a schematic diagram of a planar structure of a display area.

FIG. 5 is a schematic diagram of an equivalent circuit of a pixel drive circuit.

FIG. 6 is a working timing diagram of a pixel drive circuit.

FIG. 7 is a schematic diagram of a planar structure of a display substrate according to an exemplary embodiment of the present disclosure.

FIG. 8 is a schematic diagram of a cross-sectional structure of a display substrate according to an exemplary embodiment of the present disclosure.

FIG. 9 is a schematic diagram after a pattern of a bending region is formed according to an exemplary embodiment of the present disclosure.

FIG. 10 is a schematic diagram after a pattern of a third conductive layer is formed according to an exemplary embodiment of the present disclosure.

FIG. 11 is a schematic diagram of a structure of a first structure hole according to an exemplary embodiment of the present disclosure.

FIG. 12 is a schematic diagram of a structure of a second structure hole according to an exemplary embodiment of the present disclosure.

FIG. 13 is a schematic diagram of a planar structure of a first structure hole according to an exemplary embodiment of the present disclosure.

FIG. 14A to FIG. 14E are schematic diagrams of a manufacturing process of a metal line in according to an exemplary embodiment of the present disclosure.

FIG. 15 is a schematic diagram of a structure of another first structure hole according to an exemplary embodiment of the present disclosure.

FIG. 16 is a schematic diagram of a structure of yet another first structure hole according to an exemplary embodiment of the present disclosure.

FIG. 17 is a schematic diagram of a planar structure of another first structure hole according to an exemplary embodiment of the present disclosure.

FIG. 18 is a schematic diagram of a planar structure of yet another first structure hole according to an exemplary embodiment of the present disclosure.

FIG. 19 is a schematic diagram of a structure of another display substrate according to an exemplary embodiment of the present disclosure.

FIG. 20 is a schematic diagram of a structure of a third structure hole according to an exemplary embodiment of the present disclosure.

FIG. 21 is a schematic diagram of a structure of a fourth structure hole according to an exemplary embodiment of the present disclosure.

### DETAILED DESCRIPTION

Embodiments of the present disclosure will be described in detail hereinafter with reference to the drawings. It is to be noted that implementations may be implemented in various forms. Those of ordinary skills in the art can easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals “first”, “second”, “third”, and the like in the specification are set not to form limits in numbers but only to avoid confusion between composition elements.

In the specification, for convenience, expressions “central”, “above”, “below”, “front”, “back”, “vertical”, “horizontal”, “top”, “bottom”, “inside”, “outside” and the like for indicating directional or positional relationships are used to illustrate positional relationships between the composition elements with reference to the drawings, not to indicate or imply that involved devices or elements are required to have specific orientations or are structured and operated in the specific orientations but only to easily describe the present specification and simplify the description, and thus should not be understood as limitations on the present disclosure. The positional relationships between the constituent elements are changed as appropriate based on directions according to which the constituent elements are described. Therefore, appropriate replacements based on situations are allowed, and the positional relationships are not limited to the expressions in the specification.

In the specification, unless otherwise explicitly specified and defined, terms “mounting”, “coupling”, and “connection” should be understood in a broad sense. For example, it may be a fixed connection, or a detachable connection, or an integral connection; it may be a mechanical connection or an electrical connection; it may be a direct connection, or an indirect connection through a middleware, or an internal communication between two elements. Those of ordinary skills in the art can understand meanings of the aforementioned terms in the present disclosure according to situations.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive film” sometimes. Similarly, an “insulation film” may be replaced with an “insulation layer” sometimes.

Triangle, square, rectangle, trapezoid, pentagon or hexagon and the like in this specification are not strictly defined, and they may be approximate triangle, square, rectangle, trapezoid, pentagon or hexagon and the like. There may be some small deformation caused by tolerance, and there may be chamfer, arc edge, deformation and the like.

In the present disclosure, “about” refers to that a boundary is not defined so strictly and numerical values within a range of process and measurement errors are allowed.

At present, an OLED display apparatus has a problem of metal line breakage.

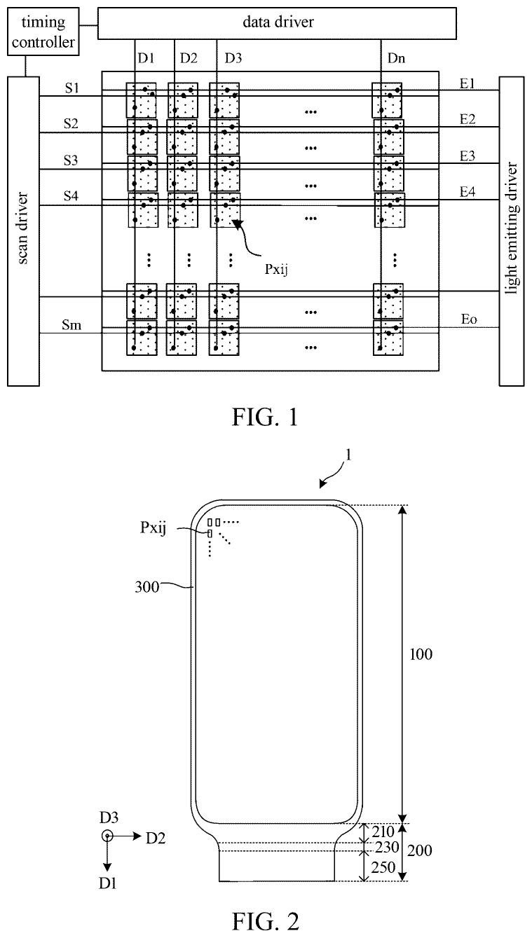

FIG. 1 is a schematic diagram of a structure of a display apparatus. As shown in FIG. 1, the display apparatus may include a timing controller, a data driver, a scan driver, a light emitting driver, and a pixel array. The timing controller is connected with the data driver, the scan driver, and the light emitting driver. The data driver is connected with multiple data signal lines (D1 to Dn). The scan driver is connected with multiple scan signal lines (S1 to Sm). The light emitting driver is connected with multiple light emitting signal lines (E1 to Eo). The pixel array may include multiple sub-pixels Pxij, wherein i and j may be natural numbers. At least one sub-pixel Pxij may include a circuit unit and a light emitting device connected to the circuit unit, and the circuit unit may include at least one scan signal line, at least one data signal line, at least one light emitting signal line, and a pixel drive circuit. In an exemplary implementation, the timing controller may provide the data driver with a grayscale value and a control signal which are suitable for the specification of the data driver, provide the scan driver with a clock signal and a scan start signal and the like which are suitable for the specification of the scan driver, and provide the light emitting driver with a clock signal and an emission stop signal and the like which are suitable for the specification of the light emitting driver. The data driver may generate data voltages to be provided to the data signal lines D1, D2, D3, . . . , and Dn using the grayscale value and the control signal that are received from the timing controller. For example, the data driver may sample the grayscale value using the clock signal and apply a data voltage corresponding to the grayscale value to the data signal lines D1 to Dn by taking a pixel row as a unit, wherein n may be a natural number. The scan driver may generate a scan signal to be provided to the scan signal lines S1, S2, S3, . . . , and Sm by receiving the clock signal, the scan start signal and the like from the timing controller. For example, the scan driver may sequentially provide scan signals with on-level pulses to the scan signal lines S1 to Sm. For example, the scan driver may be constructed in a form of a shift register and generate a scan signal in a manner of sequentially transmitting scan start signals provided in a form of an on-level pulse to a next-stage circuit under control of the clock signal, wherein m may be a natural number. The light emitting driver may generate an emission signal to be provided to the light emitting signal lines E1, E2, E3, . . . , and Eo by receiving a clock signal, an emission stop signal and the like from the timing controller. For example, the light emitting driver may sequentially provide emission signals with off-level pulses to the light emitting signal lines E1 to Eo. For example, the light emitting driver may be constructed in a form of a shift register and generate an emission signal in a manner of sequentially transmitting emission stop signals provided in a form of an off-level pulse to a next-stage circuit under control of the clock signal, wherein o may be a natural number.

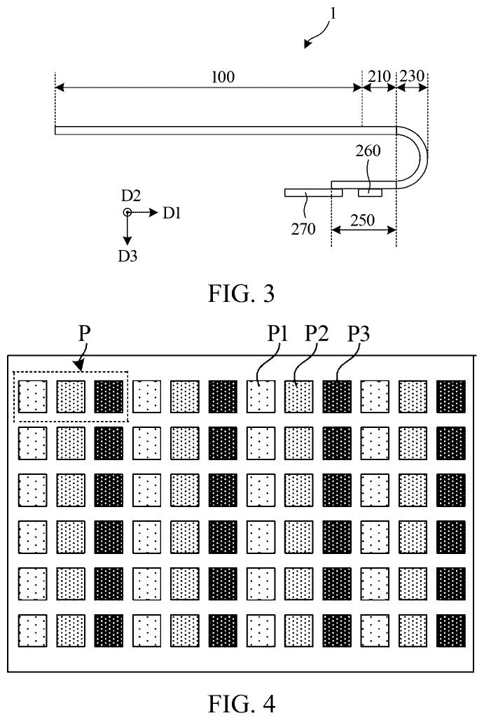

FIG. 2 is a schematic diagram of a planar structure of a display substrate, illustrating an unfolded state of a bonding area before being bent, and FIG. 3 is a side view of the display substrate in FIG. 2, illustrating a bent state of the bonding area after being bent. As shown in FIGS. 2 and 3, in a plane parallel to the display substrate 1, the display substrate 1 may include a display area 100 and an edge region located around the display area 100, and the edge region may include a bonding area 200 located on a side of the display area 100 and a bezel region 300 located on the other sides of the display area 100. For example, the bonding area 200 may be located on a side of the display area 100 in a first direction D1 (a direction away from the display area), and the bezel region 300 may be located on two sides of the display area 100 in a second direction D2 and on a side of the display area 100 in an opposite direction of the first direction D1, where the first direction D1 intersects with the second direction D2.

In an exemplary implementation, the display area 100 may include multiple sub-pixels Pxij that constitute an array of pixels, the multiple sub-pixels Pxij are configured to perform image display, and the display area 100 may be deformable, for example, may be crimped, bent, folded, or curled. The bonding area 200 may at least include an isolation dam and a bonding circuit and the bonding circuit is configured to connect signal lines of the display area 100 to an external drive apparatus. The bezel region 300 may at least include an isolation dam, a gate drive circuit, and a power supply line for transmitting voltage signals to multiple sub-pixels. The isolation dam of the bonding area 200 and the isolation dam of the bezel region 300 may be of an integral structure, and are manufactured synchronously through a same patterning process to form an annular structure surrounding the display area 100.

In an exemplary implementation, the bonding area 200 may be bent and attached to the back of the display area 100 in a bending manner, and the bonding area 200 may overlap the display area 100 in a direction perpendicular to a plane of the display area.

In an exemplary implementation, the bonding area 200 may include a lead region 210, a bending region 230, and a bonding pin region 250 sequentially provided in the first direction D1 (the direction away from the display area).

In an exemplary implementation, the lead region 210 may be provided with multiple leads. The bending region 230 may include a composite insulation layer provided with a groove, and the bending region 230 may be bent with a curvature in a third direction D3 (a direction of thickness). A surface of the bonding pin region 250 may be reversed, that is the surface of the bonding pin region 250 facing upwards may be reversed to face downwards by the bending of the bending region 230, and the third direction D3 intersects with the first direction D1. In an exemplary implementation, the bonding pin region 250 may overlap with the display area 100 in the third direction D3 when the bending region 230 is bent.

In an exemplary implementation, the bonding pin region 250 may at least include a drive chip and multiple bonding pins, the drive chip may be an integrate circuit (IC) 260, the integrate circuit 260 may be connected to multiple signal leads, and an external flexible printed circuit (FPC) 270 may be bonded and connected on the multiple bonding pins. In an exemplary implementation, the integrate circuit 260 may generate a drive signal required for driving sub-pixels and may provide the drive signal to the sub-pixels in the display area 100. For example, the drive signal may be a data signal that drives light emitting of the sub-pixel. In an exemplary implementation, the integrate circuit 260 may be bonded and connected to a drive chip region by an anisotropic conductive film or other ways. A width of the integrate circuit 260 in the second direction D2 may be less than a width of the bonding pin region 250 in the second direction D2.

FIG. 4 is a schematic diagram of a planar structure of a display area. As shown in FIG. 4, the display area may include multiple pixel units P arranged in a matrix matter. At least one of the multiple pixel units P includes a first sub-pixel P1 emitting light of a first color, a second sub-pixel P2 emitting light of a second color, and a third sub-pixel P3 emitting light of a third color, and the first sub-pixel P1, the second sub-pixel P2, and the third sub-pixel P3 may each include a pixel drive circuit and a light emitting device. The pixel drive circuit in each sub-pixel is connected with a scan signal line, a data signal line, and a light emitting signal line. The pixel drive circuit is configured to receive a data voltage transmitted by the data signal line and output a corresponding current to the light emitting device under control of the scan signal line and the light emitting signal line. The light emitting device in the sub-pixel is connected to a pixel drive circuit of a sub-pixel where the light emitting device is located, and is configured to emit light with a corresponding brightness in response to a current output by the pixel drive circuit of the sub-pixel where the light emitting device is located.

In an exemplary implementation, the first sub-pixel P1 may be a red (R) sub-pixel, the second sub-pixel P2 may be a green (G) sub-pixel, and the third sub-pixel P3 may be a blue (B) sub-pixel. In an exemplary implementation, a sub-pixel in a pixel unit may be in a shape of a rectangle, a rhombus, a pentagon, or a hexagon. Three sub-pixels may be provided side by side horizontally, side by side vertically, or in a manner like a Chinese character “ [symbol] ”. In some possible exemplary implementations, the pixel unit may include four sub-pixels, the four sub-pixels may be provided side by side horizontally, side by side vertically, in a manner to form a square, or in a manner to form a diamond, or the like, and the present disclosure is not limited herein.

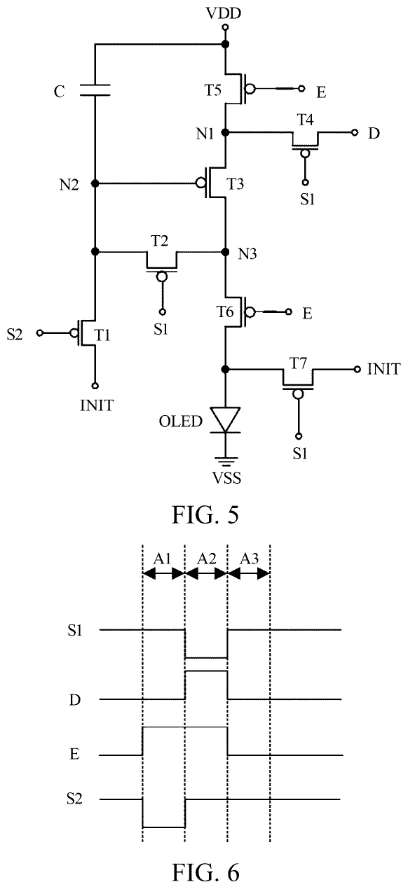

FIG. 5 is a schematic diagram of an equivalent circuit of a pixel drive circuit. In an exemplary implementation, the pixel drive circuit may be of a structure of 3T1C, 4T1C, 5T1C, 5T2C, 6T1C, or 7T1C. As shown in FIG. 5, the pixel drive circuit may include seven transistors (a first transistor T1 to a seventh transistor T7) and one storage capacitor C, and the pixel drive circuit may be connected with seven signal lines (a data signal line D, a first scan signal line S1, a second scan signal line S2, a light emitting signal line E, an initial signal line INIT, a first power supply line VDD, and a second power supply line VSS).

In an exemplary implementation, the pixel drive circuit may include a first node N1, a second node N2, and a third node N3. The first node N1 is connected with a first electrode of the third transistor T3, a second electrode of the fourth transistor T4, and a second electrode of the fifth transistor T5. The second node N2 is connected with a second electrode of the first transistor, a first electrode of the second transistor T2, a control electrode of the third transistor T3, and a second end of the storage capacitor C. The third node N3 is connected with a second electrode of the second transistor T2, a second electrode of the third transistor T3, and a first electrode of the sixth transistor T6.

In an exemplary implementation, a first end of the storage capacitor C is connected with the first power supply line VDD, and the second end of the storage capacitor C is connected with the second node N2, that is the second end of the storage capacitor C is connected with the control electrode of the third transistor T3.

The control electrode of the first transistor T1 is connected with the second scan signal line S2, the first electrode of the first transistor T1 is connected with the initial signal line INIT, and the second electrode of the first transistor is connected with the second node N2. When a scan signal with an on-level is applied to the second scan signal line S2, the first transistor T1 transmits an initialization voltage to the control electrode of the third transistor T3, so as to initialize a charge amount of the control electrode of the third transistor T3.

A control electrode of the second transistor T2 is connected with the first scan signal line S1, a first electrode of the second transistor T2 is connected with the second node N2, and a second electrode of the second transistor T2 is connected with the third node N3. When a scan signal with an on-level is applied to the first scan signal line S1, the second transistor T2 enables the control electrode of the third transistor T3 to be connected with the second electrode of the third transistor T3.

A control electrode of the third transistor T3 is connected with the second node N2, i.e., the control electrode of the third transistor T3 is connected with the second end of the storage capacitor C, a first electrode of the third transistor T3 is connected with the first node N1, and the second electrode of the third transistor T3 is connected with the third node N3. The third transistor T3 may be referred to as a drive transistor, and the third transistor T3 determines an amount of a drive current flowing between the first power supply line VDD and the second power supply line VSS according to a potential difference between the control electrode and the first electrode of the third transistor T3.

A control electrode of the fourth transistor T4 is connected with the first scan signal line S1, a first electrode of the fourth transistor T4 is connected with the data signal line D, and a second electrode of the fourth transistor T4 is connected with the first node N1. The fourth transistor T4 may be referred to as a switching transistor, a scan transistor, etc., and the fourth transistor T4 enables a data voltage of the data signal line D to be input into the pixel drive circuit when a scan signal with an on-level is applied to the first scan signal line S1.

A control electrode of the fifth transistor T5 is connected with the light emitting signal line E, a first electrode of the fifth transistor T5 is connected with the first power supply line VDD, and a second electrode of the fifth transistor T5 is connected with the first node N1. A control electrode of the sixth transistor T6 is connected with the light emitting signal line E, a first electrode of the sixth transistor T6 is connected with the third node N3, and a second electrode of the sixth transistor T6 is connected with a first electrode of a light emitting device. The fifth transistor T5 and the sixth transistor T6 may be referred to as light emitting transistors. When a light emitting signal with an on-level is applied to the light emitting signal line E, the fifth transistor T5 and the sixth transistor T6 enable the light emitting device to emit light by forming a drive current path between the first power supply line VDD and the second power supply line VSS.

The control electrode of the seventh transistor T7 is connected with the first scan signal line S1, the first electrode of the seventh transistor T7 is connected with the initial signal line INIT, and the second electrode of the seventh transistor T7 is connected with the first electrode of the light emitting device. When a scan signal with an on-level is applied to the first scan signal line S1, the seventh transistor T7 transmits an initialization voltage to the first electrode of the light emitting device so as to initialize a charge amount accumulated in the first electrode of the light emitting device or release a charge amount accumulated in the first electrode of the light emitting device.

In an exemplary implementation, the second electrode of the light emitting device is connected to the second power supply line VSS, a signal of the second power supply line VSS is a low-level signal, and a signal of the first power supply line VDD is a high-level signal continuously provided. The first scan signal line S1 is a scan signal line in a pixel drive circuit in a current display row, and the second scan signal line S2 is a scan signal line in a pixel drive circuit in a previous display row, that is, for the n-th display row, the first scan signal line S1 is S(n), and the second scan signal line S2 is S(n−1). The second scan signal line S2 in the pixel drive circuit in the current display row and the first scan signal line S1 in the pixel drive circuit in the previous display row are the same signal line, such that signal lines of a display panel can be reduced, so as to achieve a narrow bezel of the display panel.

In an exemplary implementation, the first transistor T1 to the seventh transistor T7 may be P-type transistors, or may be N-type transistors. Use of a same type of transistors in a pixel drive circuit may simplify a process flow, reduce a process difficulty of a display panel, and improve a product yield. In some possible implementations, the first transistor T1 to the seventh transistor T7 may include a P-type transistor and an N-type transistor.

In an exemplary implementation, the first scan signal line S1, the second scan signal line S2, the light emitting signal line E, and the initial signal line INIT extend in a horizontal direction, and the second power supply line VSS, the first power supply line VDD, and the data signal line D extend in a vertical direction.

In an exemplary implementation, the light emitting device may be an organic light emitting diode (OLED) including a first electrode (anode), an organic emitting layer, and a second electrode (cathode) that are stacked.

FIG. 6 is a working timing diagram of a pixel drive circuit. An exemplary embodiment of the present disclosure will be described below through a working process of the pixel drive circuit exemplified in FIG. 6. The pixel drive circuit in FIG. 6 includes seven transistors (a first transistor T1 to a seventh transistor T7) and one storage capacitor C, and the seven transistors are all P-type transistors.

In an exemplary implementation, the working process of the pixel drive circuit may include following stages.

In a first stage A1, referred to as a reset stage, a signal of the second scan signal line S2 is a low-level signal, and signals of the first scan signal line S1 and the light emitting signal line E are high-level signals. The signal of the second scan signal line S2 is the low-level signal, so that the first transistor T1 is turned on, and a signal of the initial signal line INIT is provided to the second node N2 to initialize the storage capacitor C to clear an original data voltage in the storage capacitor. The signals of the first scan signal line S1 and the light emitting signal line E are the high-level signals, so that the second transistor T2, the fourth transistor T4, the fifth transistor T5, the sixth transistor T6, and the seventh transistor T7 are turned off. An OLED does not emit light in this stage.

In a second stage A2, referred to as a data writing stage or a threshold compensation stage, a signal of the first scan signal line S1 is a low-level signal, signals of the second scan signal line S2 and the light emitting signal line E are high-level signals, and the data signal line D outputs a data voltage. In this stage, the second end of the storage capacitor C is at a low level, so the third transistor T3 is turned on. The signal of the first scan signal line S1 is the low-level signal, so that the second transistor T2, the fourth transistor T4, and the seventh transistor T7 are turned on. The second transistor T2 and the fourth transistor T4 are turned on, so that the data voltage output by the data signal line D is provided to the second node N2 through the first node N1, the turned-on third transistor T3, the third node N3, and the turned-on second transistor T2, and the storage capacitor C is charged with a difference between the data voltage output by the data signal line D and a threshold voltage of the third transistor T3. A voltage at the second end (the second node N2) of the storage capacitor C is Vd−|Vth|, wherein Vd is the data voltage output by the data signal line D, and Vth is the threshold voltage of the third transistor T3. The seventh transistor T7 is turned on, so that an initialization voltage of the initial signal line INIT is provided to a first electrode of the OLED to initialize (reset) the first electrode of the OLED and clear a pre-stored voltage therein, thereby completing initialization and ensuring that the OLED does not emit light. A signal of the second scan signal line S2 is a high-level signal, so that the first transistor T1 is turned off. A signal of the light emitting signal line E is a high-level signal, so that the fifth transistor T5 and the sixth transistor T6 are turned off.

In a third stage A3, referred to as a light emitting stage, a signal of the light emitting signal line E is a low-level signal, and signals of the first scan signal line S1 and the second scan signal line S2 are high-level signals. The signal of the light emitting signal line E is the low-level signal, so that the fifth transistor T5 and the sixth transistor T6 are turned on, and a power voltage output by the first power supply line VDD provides a drive voltage to the first electrode of the OLED through the turned-on fifth transistor T5, the third transistor T3, and the sixth transistor T6 to drive the OLED to emit light.

In a drive process of the pixel drive circuit, a drive current flowing through the third transistor T3 (drive transistor) is determined by a voltage difference between a gate electrode and the first electrode of the third transistor T3. The voltage of the second node N2 is Vdata−|Vth|, so the drive current of the third transistor T3 is as follows.

$$I = K * {( Vgs - Vth )}^{2} = K * {[ ( Vdd - Vd + \vert Vth \vert ) - Vth ]}^{2} = K * {[ Vdd - Vd ]}^{2}$$

Herein, I is the drive current flowing through the third transistor T3, i.e., a drive current for driving the OLED, K is a constant, Vgs is the voltage difference between the gate electrode and the first electrode of the third transistor T3, Vth is the threshold voltage of the third transistor T3, Vd is the data voltage output by the data signal line D, and Vdd is the power voltage output by the first power supply line VDD.

At present, in order to meet the demand of high pixel density (PPI) of OLED display products, a signal transmission line has been increased from one layer of metal to two or more layers of metal, which requires more inorganic insulation layers to block different metal layers. Since the inorganic insulation layers need to be retained in some positions and removed in other positions, a segment difference structure with a certain height difference will be produced, and the segment difference can usually reach about 2 μm. When applying a photoresist during metal patterning, since there is the segment difference structure, the photoresist at high positions where the inorganic insulation layers are retained will become thinner due to its flow to low positions where the inorganic insulation layers are removed, so that during metal etching, metal at thin positions of the photoresist will be cut off, resulting in metal line breakage, which leads to abnormal display or uneven display of products. Although the problem of line breakage can be overcome to a certain extent by increasing the coating thickness of the photoresist, increasing the coating thickness of the photoresist will lead to excessive thickness of the photoresist in low position areas, which will reduce uniformity of metal wire etching and lead to uneven display and the like problems.

An exemplary embodiment of the present disclosure provides a display substrate, including a display area and a bonding area located on a side of the display area. The bonding area includes a lead region, a first transition region, a bending region, a second transition region, and a bonding pin region sequentially provided in a direction away from the display area. In a plane perpendicular to the display substrate, the lead region and the bonding pin region each include a composite insulation layer provided on a base substrate and a metal line provided on a side of the composite insulation layer away from the base substrate. The first transition region and the second transition region each include a composite insulation layer provided on the base substrate, an inorganic insulation layer provided on a side of the composite insulation layer away from the base substrate, and a metal line provided on a side of the inorganic insulation layer away from the base substrate. The bonding area is further provided with a structure hole for maintaining photoresist thicknesses of the first transition region and the second transition region.

In an exemplary implementation, at least one structure hole is provided in at least one or more of the lead region, the first transition region, the second transition region, and the bonding pin region, and the structure hole is provided in the metal line.

In an exemplary implementation, at least one structure hole is provided in at least one or more of the first transition region and the second transition region, and the structure hole is provided in the inorganic insulation layer.

In an exemplary implementation, a shape of the structure hole includes any one or more of the following: a triangle, a rectangle, a pentagon, a hexagon, a circle, and an ellipse.

In an exemplary implementation, the structure hole has a circular shape, and a diameter of the structure hole is greater than or equal to ¼ of a width of the metal line. The diameter of the structure hole is less than or equal to ⅔ of the width of the metal line, and the width of the metal line is a dimension perpendicular to an extension direction of the metal line.

In an exemplary implementation, the multiple structure holes have the same area.

In an exemplary implementation, areas of the multiple structure holes are gradually increased in a direction away from the display area, or areas of the multiple structure holes are gradually increased in a direction close to the display area.

In an exemplary implementation, areas of the multiple structure holes in the lead region are gradually increased in a direction away from the first transition region. Areas of the multiple structure holes in the first transition region are gradually increased in a direction away from the lead region. Areas of the multiple structure holes in the second transition region are gradually increased in a direction away from the bonding pin region. Areas of the multiple structure holes in the bonding pin region are gradually increased in a direction away from the second transition region.

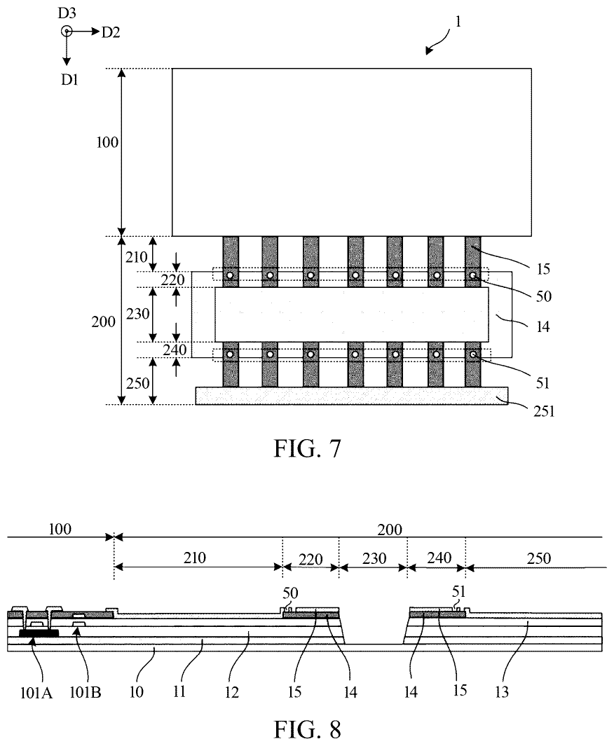

FIG. 7 is a schematic diagram of a planar structure of a display substrate according to an exemplary embodiment of the present disclosure. As shown in FIG. 7, in a plane parallel to the display substrate, the display substrate 1 may include a display area 100 and a bonding area 200 located on a side of the display area. The bonding area 200 may include a lead region 210, a first transition region 220, a bending region 230, a second transition region 240, and a bonding pin region 250 that are provided sequentially in a first direction D1 (a direction away from the display area). The lead region 210 may be connected to the display area 100, the first transition region 220 may be connected to the lead region 210, the bending region 230 may be connected to the first transition region 220, the second transition region 240 may be connected to the bending region 230, and the bonding pin region 250 may be connected to the second transition region 240.

In an exemplary implementation, the lead region 210 may be provided with multiple signal leads, a first power supply line, and a second power supply line. Data leads of the multiple signal leads are configured to be connected with data lines of the display area 100 in a fanout wiring manner. Touch leads of the multiple signal leads are configured to be connected with touch electrodes of the display area 100. A first power supply line is configured to be connected with a high voltage power supply line (VDD) of the display area 100, and a second power supply line is configured to be connected with a low voltage power supply line (VSS) of a bezel region.

In an exemplary implementation, the bending region 230 may include a composite insulation layer provided with a groove, and the bonding pin region 250 may be bent and attached to a back of the display area 100 using the groove of the bending region 230.

In an exemplary implementation, the bonding pin region 250 may at least include multiple bonding pins 251 and multiple signal connection lines. The multiple bonding pins 251 are configured to be bonded and connected to an external flexible printed circuit (FPC), and the multiple signal connection lines are configured to be connected correspondingly to the multiple bonding pins 251.

In an exemplary implementation, a first direction D1 may be an extension direction (a column direction) of the data signal lines in the display area, a second direction D2 may be an extension direction (a row direction) of the scan signal lines in the display area, and a third direction D3 may be a direction perpendicular to a plane of the display substrate (a thickness direction). The first direction D1 and the second direction D2 may be perpendicular to each other, and the first direction D1 and the third direction D3 may be perpendicular to each other.

Since an inorganic insulation layer 14 is retained in the first transition region 220 and the second transition region 240, and the inorganic insulation layer is removed in an area of the first transition region 220 on a side close to the display area 100 (as shown in the lead region 210 in FIG. 7), there will be a high and low segment difference structure (as shown in an upper dashed line box in FIG. 7) on a side of the first transition region 220 close to the display area 100. The inorganic insulation layer is removed in an area of the second transition region 240 on a side away from the display area 100 (as shown in the bonding pad region 250 in FIG. 7), thus there will be a high and low segment difference structure (as shown in a lower dashed line box in FIG. 7) on a side of the second transition region 240 away from the display area 100. When the metal lines 15 are manufactured by a patterning process, a junction area between the first transition region 220 and the lead region 210 on a side of the first transition region 220 close to the display area 100 and a junction area between the second transition region 240 and the bonding pin region 250 on a side of the second transition region 240 away from the display area 100 are areas prone to metal line breakage. An embodiment of the present disclosure reduces the risk of metal line breakage by providing structure holes that maintain the photoresist thicknesses of the first transition region and the second transition region in the bonding area, such as by providing structure holes that maintain the photoresist thicknesses of the first transition region and the second transition region in at least one or more of the lead region, the first transition region, the second transition region, and the bonding pin region.

In an exemplary implementation, at least one first structure hole 50 is provided in a junction area between the first transition region 220 and the lead region 210 on a side of the first transition region 220 close to the display area 100.

In an exemplary implementation, at least one second structure hole 51 is provided in a junction area between the second transition region 240 and the bonding pin region 250 on a side of the second transition region 240 away from the display area 100.

FIG. 8 is a schematic diagram of a cross-sectional structure of a display substrate according to an exemplary embodiment of the present disclosure. In a plane parallel to the display substrate, the bonding area 200 may include a lead region 210, a first transition region 220, a bending region 230, a second transition region 240, and a bonding pin region 250 that are provided sequentially in a first direction D1 (a direction away from the display area). The lead region 210 may be connected to the display area 100, the first transition region 220 may be connected to the lead region 210, the bending region 230 may be connected to the first transition region 220, the second transition region 240 may be connected to the bending region 230, and the bonding pin region 250 may be connected to the second transition region 240.

In an exemplary implementation, in a plane perpendicular to the display substrate, the display area 100 may include a base substrate, a drive structure layer provided on the base substrate, a light emitting structure layer provided on a side of the drive structure layer away from the base substrate, a encapsulation structure layer provided on a side of the light emitting structure layer away from the base substrate, and a touch structure layer provided on a side of the encapsulation structure layer away from the base substrate.

In an exemplary implementation, the drive structure layer of the display area 100 may include a first insulation layer 11 provided on the base substrate 10, a semiconductor layer provided on a side of the first insulation layer 11 away from the base substrate, a second insulation layer 12 provided on a side of the semiconductor layer away from the base substrate, a first conductive layer provided on a side of the second insulation layer 12 away from the base substrate, a third insulation layer 13 provided on a side of the first conductive layer away from the base substrate, a second conductive layer provided on a side of the third insulation layer 13 away from the base substrate, a fourth insulation layer 14 provided on a side of the second conductive layer away from the base substrate, and a third conductive layer provided on a side of the fourth insulation layer 14 away from the base substrate. In an exemplary implementation, the semiconductor layer may at least include active layers of multiple transistors, the first conductive layer may at least include gate electrodes of the multiple transistors and a first electrode plate of a storage capacitor, the second conductive layer may at least include a second electrode plate of the storage capacitor, and the third conductive layer may at least include first electrodes and second electrodes of the multiple transistors. Illustration is made in FIG. 8 by taking one transistor 101A and one storage capacitor 101B of the display area 100 as an example.

In an exemplary implementation, in a plane perpendicular to the display substrate, the lead region 210 and the bonding pin region 250 include a composite insulation layer (including the first insulation layer 11, the second insulation layer 12, and the third insulation layer 13) provided on the base substrate 10 and a metal line 15 provided on a side of the composite insulation layer away from the base substrate 10. The first transition region 220 and the second transition region 240 include a composite insulation layer (including the first insulation layer 11, the second insulation layer 12, and the third insulation layer 13) provided on the base substrate 10, an inorganic insulation layer 14 provided on a side of the composite insulation layer away from the base substrate 10, and a metal line 15 provided on a side of the inorganic insulation layer 14 away from the base substrate 10. The bonding area 200 further includes a first structure hole 50 and a second structure hole 51 that maintain the photoresist thicknesses of the first transition region 220 and the second transition region 240.

In an exemplary implementation, the first transition region 220 includes a first structure hole 50. The first structure hole 50 of the first transition region 220 is provided in an area of the first transition region 220 close to the lead region 210 and the first structure hole 50 may be provided in the metal line 15.

In an exemplary implementation, the second transition region 240 includes a second structure hole 51. The second structure hole 51 of the second transition region 240 is provided in an area of the second transition region 240 close to the bonding pin region 250 and the second structure hole 51 may be provided in the metal line 15.

Taking the display area 100 and the bonding area 200 as an example, a manufacturing process of the display substrate is described below by way of example. A “patterning process” mentioned in the embodiments of the present disclosure includes a treatment such as photoresist coating, mask exposure, development, etching, and photoresist stripping for a metal material, an inorganic material, or a transparent conductive material, and includes a treatment such as organic material coating, mask exposure, and development for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. In the present disclosure, “A and B are disposed on the same layer” indicates that A and B are simultaneously formed by the same patterning process, and a “thickness” of the film layer is a dimension of the film layer in a direction perpendicular to the display substrate. In an exemplary embodiment of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A overlaps with the boundary of the orthographic projection of B.

The manufacturing process of the display substrate according to an exemplary embodiment of the present disclosure may include following acts.

(1) Forming a pattern of a bending region. In an exemplary implementation, forming a pattern of a bending region may include:
A, first manufacturing a base substrate 10 on a glass underlay substrate 2, then depositing sequentially a first insulation thin film and a semiconductor thin film on the base substrate 10, and patterning the semiconductor thin film by a patterning process to form a first insulation layer 11 covering the entire base substrate 10 and a pattern of a semiconductor layer provided on the first insulation layer 11. The pattern of the semiconductor layer at least includes an active layer located in the display area 100. After this patterning process, the bonding area 200 may include the first insulation layer 11 provided on the base substrate 10.
B, subsequently, depositing sequentially a second insulation thin film and a first conductive thin film and patterning the first conductive thin film through a patterning process to form a second insulation layer 12 covering the pattern of the semiconductor layer and a pattern of a first conductive layer provided on the second insulation layer 12. The pattern of the first conductive layer at least includes a gate electrode and a first electrode plate located in the display area 100. After this patterning process, the bonding area 200 may include the first insulation layer 11 and the second insulation layer 12 stacked on the base substrate 10. In an exemplary implementation, the first conductive layer may be referred to as a first gate metal (GATE1) layer.
C, subsequently, depositing sequentially a third insulation thin film and a second conductive thin film and patterning the second conductive thin film through a patterning process to form a third insulation layer 13 covering the first conductive layer, and a pattern of a second conductive layer provided on the third insulation layer 13. The pattern of the second conductive layer at least includes a second electrode plate located in the display area 100. An orthographic projection of the second electrode plate on the base substrate at least partially overlaps with an orthographic projection of the first electrode plate on the base substrate. After this patterning process, the lead region 210 and the bending region 230 of the bonding area 200 may include the first insulation layer 11, the second insulation layer 12, and the third insulation layer 13 stacked on the base substrate 10. In an exemplary implementation, the second conductive layer may be referred to as a second gate metal (GATE2) layer.
D, subsequently, depositing a fourth insulation thin film and patterning the fourth insulation thin film by a patterning process to form a pattern of an inorganic insulation layer 14 and a bending groove 231. The bending groove 231 is provided in a bending region 230 of the bonding area 200.

In an exemplary implementation, a groove structure consisting of a first groove and a second groove can be formed by two patterning processes using two masks (Etch Bending A MASK (EBA MASK) and Etch Bending B MASK (EBB MASK)). The first groove and the second groove together form a bending groove 231, in which the inorganic insulation layer 14, the third insulation layer 13, the second insulation layer 12 and the first insulation layer 11 are removed to expose a surface of the base substrate 10.

In an exemplary implementation, in a patterning process using a mask (EBA MASK), the inorganic insulation layer 14 in the lead region 210 and the bonding pin region 250 may further be removed, retaining only the inorganic insulation layer 14 in the first transition region 220 and the second transition region 230 in the bonding area 200.

In an exemplary implementation, in a patterning process using a mask, two vias K1 and K2 are further formed in the display area 100.

In an exemplary implementation, the EBA MASK and the EBB MASK processes are patterning processes for grooving a bending region of a display substrate, which can reduce a thickness of the bending region. In an exemplary implementation, in the EBB MASK process, a portion of a thickness of the base substrate in the bending groove 231 may be etched away, for example a second barrier layer of the base substrate is etched away, and the present disclosure is not limited herein.

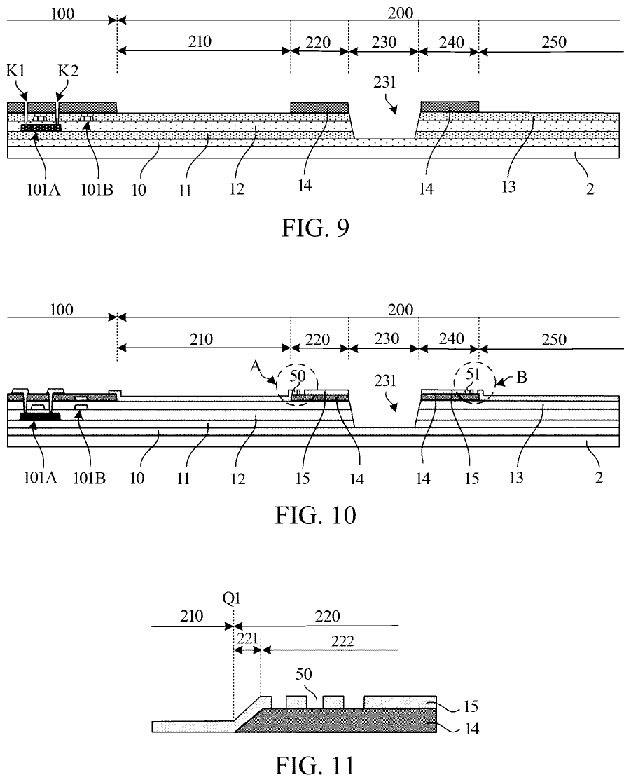

So far, the manufacturing of the pattern of the bending region is completed, as shown in FIG. 9.

After this patterning process, the display area 100 may include a base substrate 10 provided on a glass underlay substrate 2, and a first insulation layer 11, a semiconductor layer, a second insulation layer 12, a first conductive layer, a third insulation layer 13, a second conductive layer, and an inorganic insulation layer 14 stacked on the base substrate 10. The lead region 210 and the bonding pin region 250 of the bonding area 200 may include a base substrate 10 and a first insulation layer 11, a second insulation layer 12, and a third insulation layer 13 stacked on the base substrate 10. The bending region 230 may include the base substrate 10 and a bending groove provided on the base substrate 10. The first transition region 220 and the second transition region 240 of the bonding area 200 may include a base substrate 10 and a first insulation layer 11, a second insulation layer 12, a third insulation layer 13 and an inorganic insulation layer 14 stacked on the base substrate 10.

In an exemplary implementation, the first insulation layer 11, the second insulation layer 12, and the third insulation layer 13 may be referred to as a composite insulation layer.

In an exemplary implementation, the base substrate may include a first flexible material layer, a first inorganic material layer, a semiconductor layer, a second flexible material layer and a second inorganic material layer stacked on the glass underlay substrate. Materials of the first flexible material layer and the second flexible material layer may be polyimide (PI), polyethylene terephthalate (PET), or surface treated polymer soft film, etc. Materials of the first inorganic material layer and the second inorganic material layer may be silicon nitride (SiNx), silicon oxide (SiOx), or the like, for improving water and oxygen resistance of a base substrate. The first inorganic material layer and the second inorganic material layer may also be referred to as barrier layers, and the material of the semiconductor layer may be amorphous silicon (a-si). Taking a stacked structure of PI1/Barrier1/a-si/PI2/Barrier2 as an example, its manufacturing process may include: first coating a layer of polyimide on a glass underlay substrate, after the layer of polyimide is cured to form a film, a first flexible (PI1) layer is formed; then depositing a layer of barrier film on the first flexible layer to form a first barrier (Barrier 1) layer covering the first flexible layer; then depositing a layer of amorphous silicon film on the first barrier layer to form an amorphous silicon (a-si) layer covering the first barrier layer; then coating another layer of polyimide on the amorphous silicon layer, after this layer of polyimide is cured to form a film, a second flexible (PI2) layer is formed; and then depositing a layer of barrier film on the second flexible layer to form a second barrier (Barrier 2) layer covering the second flexible layer, so as to complete the manufacturing of the base substrate.

In an exemplary implementation, the first insulation layer, the second insulation layer, the third insulation layer, and the inorganic insulation layer may be made of any one or more of silicon oxide (SiOx), silicon nitride (SiNx) and silicon oxynitride (SiON), and may be single-layer, multi-layers or composite layers. The first insulation layer may be referred to as a buffer layer, and the second insulation layer and the third insulation layer may be referred to as (GI) layers. The first conductive layer, the second conductive layer, and the third conductive layer may be made of a metal material, such as any one or more of Silver (Ag), Copper (Cu), Aluminum (Al), Titanium (Ti), and Molybdenum (Mo), or an alloy material of the aforementioned metals, such as an Aluminum Neodymium alloy (AlNd) or a Molybdenum Niobium alloy (MoNb), and may be of a single-layer structure or a multi-layer composite structure, such as Ti/A1/Ti.

(2) Forming a third conductive layer. In an exemplary implementation, forming the third conductive layer may include depositing a third conductive thin film on the base substrate on which the aforementioned patterns are formed, and patterning the third conductive thin film by a patterning process to form a pattern of the third conductive layer. The third conductive layer at least includes multiple metal lines 15 extending from the display area 100 to the bonding pin region 250, as shown in FIG. 10. In an exemplary implementation, the third conductive layer may be referred to as a first source-drain metal (SD1) layer.

In an exemplary implementation, the inorganic insulation layers are retained in the first transition region 220 and the second transition region 240, and the first transition region 220 and the second transition region 240 may be referred to as an inorganic insulation layer retained area. The inorganic insulation layer on a side of the first transition region 220 close to the display area 100, for example the lead region 210, is removed, and the inorganic insulation layer on a side of the second transition region 240 away from the display area 100, for example the bonding pin region 250, is removed. The lead region 210 and the bonding pin region 250 may be referred to as an inorganic insulation layer removed area. A junction area between the first transition region 220 and the lead region 210 and a junction area between the second transition region 240 and the bonding pin region 250 both exhibit a high and low segment difference structure and are areas prone to metal line breakage. An embodiment of the present disclosure may reduce a risk of metal line breakage by providing structure holes in the first transition region 220 and the second transition region 240.

In an exemplary implementation, the first transition region 220 may include a first structure hole 50, and the first structure hole 50 of the first transition region 220 may be provided in a metal line 15. A depth of the first structure hole 50 may be equal to a thickness of the metal line 15, that is, the first structure hole 50 may be a through hole penetrating through the metal line.

In an exemplary implementation, the second transition region 240 may include a second structure hole 51, and the second structure hole 51 of the second transition region 240 may be provided in a metal line 15. A depth of the second structure hole 51 may be equal to a thickness of the metal line 15, that is, the second structure hole 51 may be a through hole penetrating through the metal line.

FIG. 11 is a schematic diagram of a structure of a first structure hole according to an exemplary embodiment of the present disclosure, which is a schematic partial enlarged view of a position A in FIG. 10. As shown in FIG. 11, there is a first junction position Q1 between the first transition region 220 and the lead region 210. Multiple first structure holes 50 of the first transition region 220 may be provided in an area of the first transition region 220 close to the first junction position Q1 with respect to the first junction position Q1.

In an exemplary implementation, the first transition region 220 may include a first climbing region 221 and a first planarization region 222. The first climbing region 221 may be located on a side of the first junction position Q1 away from the lead region 210, and the first planarization region 222 may be located on a side of the first climbing region 221 away from the first junction position Q1.

In an exemplary implementation, multiple first structure holes 50 may be provided in the metal lines 15 of the first planarization region 222.

In an exemplary implementation, in a plane parallel to the base substrate, a shape of a first structure hole 50 may include any one or more of the following: a triangle, a rectangle, a pentagon, a hexagon, a circle, and an ellipse.

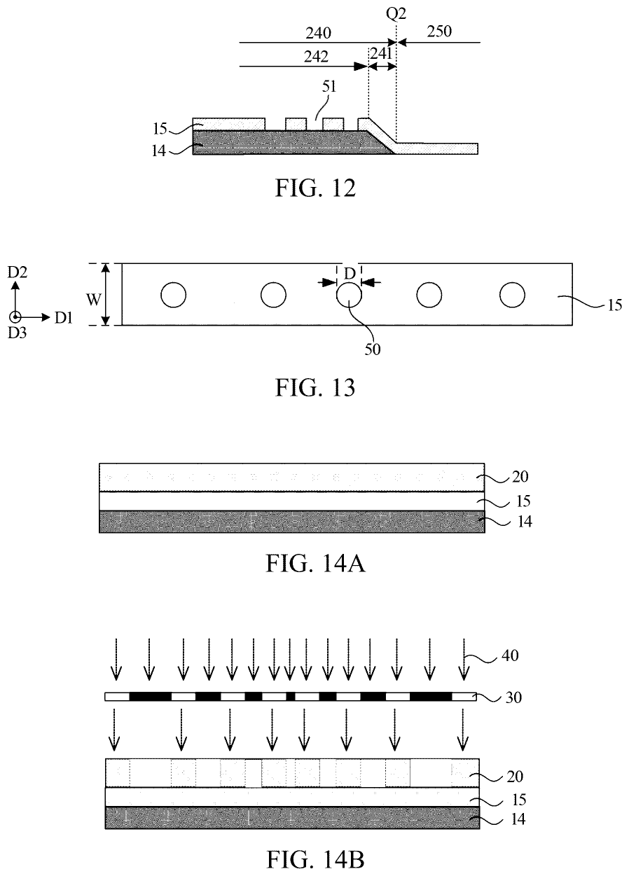

FIG. 12 is a schematic diagram of a structure of a second structure hole according to an exemplary embodiment of the present disclosure, which is a schematic partial enlarged view of a position B in FIG. 10. As shown in FIG. 12, there is a second junction position Q2 between the second transition region 240 and the bonding pin region 250. Multiple second structure holes 51 of the second transition region 240 may be provided in an area of the second transition region 240 close to the second junction position Q2 with respect to the second junction position Q2.

In an exemplary implementation, the metal line 15 of the second transition region 240 may include a second climbing region 241 and a second planarization region 242. The second climbing region 241 may be located on a side of the second junction position Q2 away from the bonding pin region 250, and the second planarization region 242 may be located on a side of the second climbing region 241 away from the second junction position Q2.

In an exemplary implementation, multiple second structure holes 51 may be provided in the metal lines 15 of the second planarization region 242.

In an exemplary implementation, in the plane parallel to the base substrate, a shape of a second structure hole 51 may include any one or more of the following: a triangle, a rectangle, a pentagon, a hexagon, a circle, and an ellipse.

FIG. 13 is a schematic diagram of a planar structure of a first structure hole according to an exemplary embodiment of the present disclosure taking a circular structure hole as an example. As shown in FIG. 13, the metal line 15 is a line shape extending in the first direction D1, the metal line 15 has a width W in the second direction D2, and the width W of the metal line may be a dimension perpendicular to an extension direction of the metal line (in the second direction D2). In a plane parallel to the base substrate, a first structure hole 50 may have a circular shape and a diameter D.

In an exemplary implementation, multiple first structure holes 50 may have the same diameter in the first direction D1. That is, the multiple first structure holes 50 may have the same area.

In an exemplary implementation, multiple second structure holes 51 may have the same diameter in the first direction D1. That is, the multiple second structure holes 51 may have the same area.

In an exemplary implementation, a diameter D of the first structure hole or the second structure hole may be greater than or equal to ¼ of a width W of the metal line.

In an exemplary implementation, the diameter D of the first structure hole or the second structure hole may be less than or equal to ⅔ of the width W of the metal line.

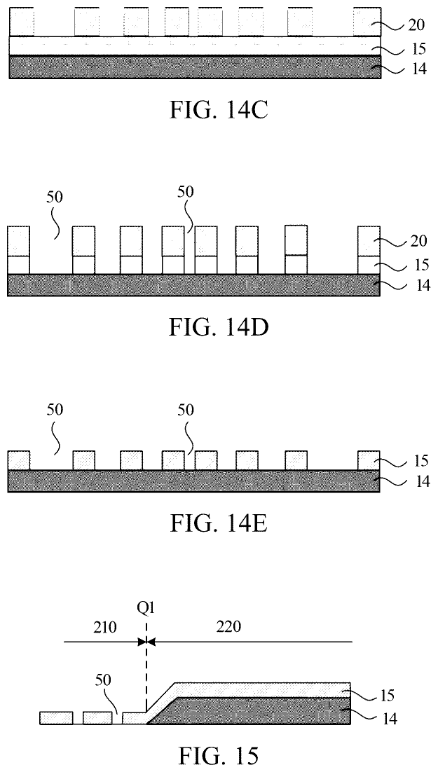

FIGS. 14A to 14E are schematic diagrams of a manufacturing process of a metal line according to an exemplary embodiment of the present disclosure. A metal thin film 15 is deposited on the inorganic insulation layer 14 of the first transition region 220, and then a photoresist 20 is coated on the metal thin film 15 (as shown in FIG. 14A, the photoresist in this embodiment is a negative photoresist). Subsequently, exposure is made by ultraviolet light 40 using a mask 30 and the light passes through the fully transmissive area so that the area becomes a fully exposed area (as shown in FIG. 14B). After development, the photoresist in the fully exposed area is completely retained because it is insoluble in the developer, and becomes a completely retained photoresist area, while the unexposed part is dissolved in the developer, and becomes a completely removed photoresist area (as shown in FIG. 14C). Subsequently, the metal thin film in an area other than the pattern of photoresist is removed by an etching process (as shown in FIG. 14D). Finally, the remaining photoresist is peeled off and a metal line 15 having a pattern of a structure hole 50 is formed (as shown in FIG. 14E).

In an exemplary implementation, a positive photoresist may also be coated on the metal thin film for subsequent exposure, development and the like.

In an exemplary implementation, a similar patterning method may be used to coat a film layer on the base substrate on which the aforementioned patterns are formed and pattern the film layer to form other layers, including but not limited to, a first planarization layer, a fourth conductive layer (a second source-drain metal (SD2) layer), a second planarization layer, and an anode conductive (AND) layer.

In an embodiment of the present disclosure, at least one structure hole is provided in a metal line in an area where the inorganic insulation layer is retained (such as the first transition region or the second transition region). In this way, the embodiment of the present disclosure reduces the amount of photoresist flowing from a high position (such as the first transition region or the second transition region) to a low position (such as the lead region or the bonding pin region) due to a segment difference structure between two adjacent regions (such as between the first transition region and the lead region or between the second transition region and the bonding pin region) during photoresist coating when patterning, and even completely prevents the photoresist at the high position from flowing to the low position, thereby avoiding the photoresist at the high position being too thin to cause the metal at the high position to be exposed and etched, and reducing the risk of metal line breakage.

FIG. 15 is a schematic diagram of a structure of another first structure hole according to an exemplary embodiment of the present disclosure, which is a schematic partial enlarged view of a position A in FIG. 10. As shown in FIG. 15, the main body structure of the display substrate of this embodiment is substantially the same as that of a foregoing embodiment, except that the first structure hole 50 may be provided in the lead region 210, and multiple first structure holes 50 may be provided in an area of the lead region 210 close to the first junction position Q1.

In an exemplary implementation, the first structure hole 50 of the lead region 210 may be provided in an area of the lead region 210 close to the first transition region 220, and the first structure hole 50 may be provided in the metal line 15.

In an exemplary implementation, the second structure hole 51 of the bonding pin region 250 may be provided in an area of the bonding pin region 250 close to the second transition region 240, and the second structure hole 51 may be provided in the metal line 15.

In an embodiment of the present disclosure, at least one structure hole is provided in a metal line in an area where the inorganic insulation layer is not retained (such as a lead region adjacent to the first transition region or a bonding pin region adjacent to the second transition region) adjacent to an area where the inorganic insulation layer is retained. In this way, the embodiment of the present disclosure can make the thickness of photoresist at a high position and a low position tend to be the same, thereby avoiding the photoresist at the high position being too thin to cause the metal at the high position to be exposed and etched, and reducing the risk of metal line breakage.

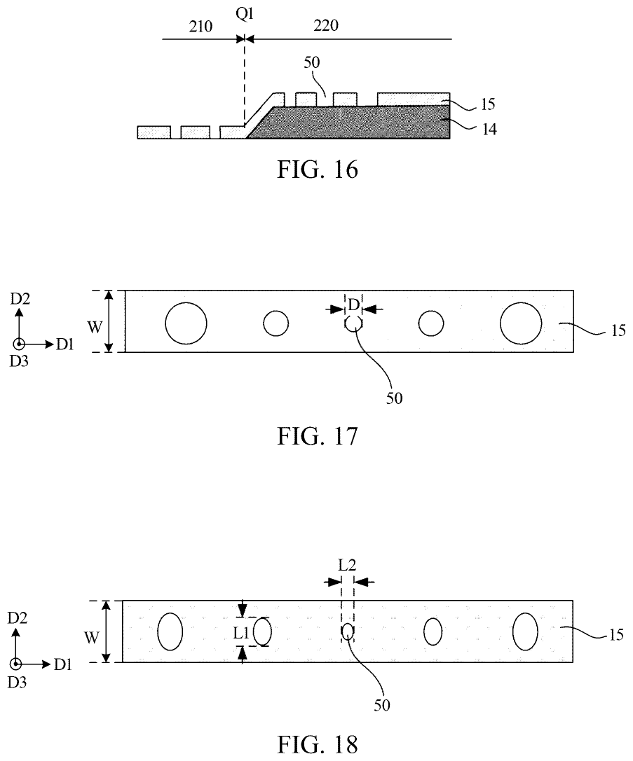

FIG. 16 is a schematic diagram of a structure of yet another first structure hole according to an exemplary embodiment of the present disclosure, which is a schematic partial enlarged view of a position A in FIG. 10. As shown in FIG. 16, the main body structure of the display substrate of this embodiment is substantially the same as that of a foregoing embodiment, except that the first structure hole 50 may be provided in two positions, i.e. the lead region 210 and the first transition region 220, and multiple first structure holes 50 may be provided in an area of the lead region 210 close to the first junction position Q1 and an area of the first transition region 220 close to the first junction position Q1.

In an exemplary implementation, the first structure hole 50 of the lead region 210 may be provided in an area of the lead region 210 close to the first transition region 220, and the first structure hole 50 may be provided in the metal line 15. The first structure hole 50 of the first transition region 220 may be provided in an area of the first transition region 220 close to the lead region 210, and the first structure hole 50 may be provided in the metal line 15

In an exemplary implementation, the second structure hole 51 may be provided in two positions, i.e. the second transition region 240 and the bonding pin region 250. The second structure hole 51 of the bonding pin region 250 may be provided in an area of the bonding pin region 250 close to the second transition region 240 and the second structure hole 51 may be provided in the metal line 15. The second structure hole 51 of the second transition region 240 may be provided in an area of the second transition region 240 close to the bonding pin region 250 and the second structure hole 51 may be provided in the metal line 15.

In an embodiment of the present disclosure, multiple structure holes are provided in the metal lines of the two areas, that is, the multiple structure holes are provided in the metal lines in areas where the inorganic insulation layer is retained (such as the first transition region or the second transition region) and the adjacent area where the inorganic insulation layer is not retained (such as the lead region adjacent to the first transition region or the bonding pin region adjacent to the second transition region). In this way, the embodiment of the present disclosure slows down a flow of photoresist from the high position to the low position, which is beneficial to making the thickness of photoresist at the high position and low position tend to be the same, and maximally avoids a risk of metal line breakage when photoresist at the high position where the photoresist thickness is thin due to excessive difference in photoresist thickness is etched.

FIG. 17 is a schematic diagram of a planar structure of another first structure hole according to an exemplary embodiment of the present disclosure taking a circular structure hole as an example. As shown in FIG. 17, multiple first structure holes 50 may adopt a structure in which an area is gradually changed.

In an exemplary implementation, an area of the multiple first structure holes 50 is gradually increased in a direction away from the display area 100 or an area of the multiple first structure holes 50 is gradually increased in a direction close to the display area 100.

In an exemplary implementation, an area of the multiple first structure holes 50 in the lead region 210 is gradually increased in a direction away from the first transition region 220.

In an exemplary implementation, an area of the multiple first structure holes 50 in the first transition region 220 is gradually increased in a direction away from the lead region 210.

In an exemplary implementation, the multiple second structure holes 51 may adopt a structure in which an area is gradually changed.

In an exemplary implementation, an area of the multiple second structure holes 51 in the second transition region 240 is gradually increased in a direction away from the bonding pin region 250.

In an exemplary implementation, an area of the multiple second structure holes 51 in the bonding pin region 250 is gradually increased in a direction away from the second transition region 240.

FIG. 18 is a schematic diagram of a planar structure of yet another first structure hole according to an exemplary embodiment of the present disclosure taking an elliptical structure hole as an example. As shown in FIG. 18, the metal line 15 is a line shape extending in the first direction D1, and the metal line 15 has a width W in the second direction D2, that is, the width of the metal line is a dimension perpendicular to an extension direction of the metal line. In a plane parallel to the base substrate, the first structure hole 50 may have an elliptical shape, and have a major axis L1 extending in the second direction D2 and a minor axis L2 extending in the first direction D1. The multiple first structure holes 50 may adopt a structure in which an area of an ellipse is gradually changed.

In an exemplary implementation, an area of the multiple first structure holes 50 in the lead region 210 is gradually increased in a direction away from the first transition region 220.

In an exemplary implementation, an area of the multiple first structure holes 50 in the first transition region 220 is gradually increased in a direction away from the lead region 210.

In a plane parallel to the base substrate, the second structure hole 51 may have an elliptical shape, and have a major axis L1 extending in the second direction D2 and a minor axis L2 extending in the first direction D1. The multiple second structure holes 51 may adopt a structure in which an area of an ellipse is gradually changed.

In an exemplary implementation, an area of the multiple second structure holes 51 in the second transition region 240 is gradually increased in a direction away from the bonding pin region 250.

In an exemplary implementation, an area of the multiple second structure holes 51 in the bonding pin region 250 is gradually increased in a direction away from the second transition region 240.

In an exemplary implementation, the major axis L1 of the first structure hole or the second structure hole may be less than or equal to ⅔ of a width W of the metal line.

In an exemplary implementation, the minor axis L2 of the first structure hole or the second structure hole may be greater than or equal to ¼ of a width W of the metal line.

The first structure hole or the second structure may also have other shapes, sizes, or arrangements, and will not be repeated herein.

In an embodiment of the present disclosure, at least one structure hole is provided in at least one of the areas where the inorganic insulation layer is retained (such as the first transition region or the second transition region) and the adjacent area where the inorganic insulation layer is not retained (such as the lead region adjacent to the first transition region or the bonding pin region adjacent to the second transition region) and a quantity, shape, size and other parameters of the structure hole may be changed. In this way, the embodiment of the present disclosure can further reduce or slow down a flow of photoresist from the high position to the low position, make the thicknesses of photoresist at the high position and low position tend to be the same, and avoid a risk of metal line breakage when photoresist at the high position where the photoresist thickness is thin due to excessive difference in photoresist thickness is etched.

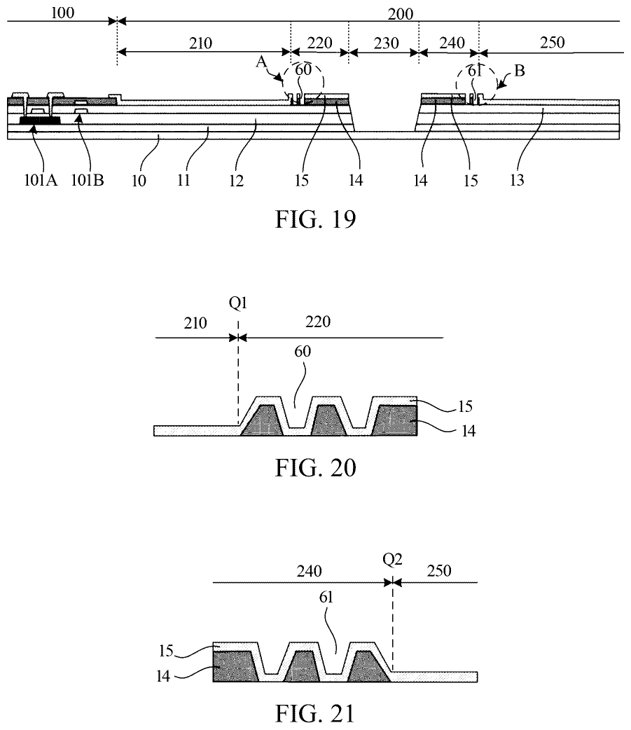

FIG. 19 is a schematic diagram of a structure of another display substrate according to an exemplary embodiment of the present disclosure. As shown in FIG. 19, an inorganic insulation layer is retained in the first transition region 220 and the second transition region 240, and the first transition region 220 and the second transition region 240 may be referred to as an inorganic insulation layer retained area. An inorganic insulation layer on a side of the first transition region 220 close to the display area 100 is removed, and an inorganic insulation layer on a side of the second transition region 240 away from the display area 100 is removed. The lead region 210 and the bonding pin region 250 may be referred to as an inorganic insulation layer removed area. The junction area between the first transition region 220 and the lead region 210 and the junction area between the second transition region 240 and the bonding pin region 250 both exhibit a high and low segment difference structure and are areas prone to metal line breakage. An embodiment of the present disclosure may reduce a risk of metal line breakage by providing structure holes in the first transition region 220 and the second transition region 240.

In an exemplary implementation, the first transition region 220 may include a third structure hole 60, and the third structure hole 60 of the first transition region 220 may be provided in the inorganic insulation layer 14. A depth of the third structure hole 60 may be equal to a thickness of the inorganic insulation layer 14, that is, the third structure hole 60 may be a through hole penetrating through the inorganic insulation layer.

In an exemplary implementation, the second transition region 240 may include a fourth structure hole 61 and the fourth structure hole 61 of the second transition region 240 may be provided in the inorganic insulation layer 14. A depth of the fourth structure hole 61 may be equal to a thickness of the inorganic insulation layer 14, that is, the fourth structure hole 61 may be a through hole penetrating through the metal line.

FIG. 20 is a schematic diagram of a structure of a third structure hole according to an exemplary embodiment of the present disclosure, which is a schematic partial enlarged view of a position A in FIG. 19. As shown in FIG. 20, there is a first junction position Q1 between the first transition region 220 and the lead region 210. Multiple third structure holes 60 of the first transition region 220 may be provided in an area of the first transition region 220 close to the first junction position Q1 with respect to the first junction position Q1.

In an exemplary implementation, the third structure hole 60 of the first transition region 220 may be provided in an area of the first transition region 220 close to the lead region 210 and the third structure hole 60 may be provided in the inorganic insulation layer 14.

In an exemplary implementation, a metal line 15 covers a hole wall and a hole bottom of a third structure hole 60.

In an exemplary implementation, in a plane parallel to the base substrate, a shape of the first structure hole 60 may include any one or more of the following: a triangle, a rectangle, a pentagon, a hexagon, a circle, and an ellipse.

FIG. 21 is a schematic diagram of a structure of a fourth structure hole according to an exemplary embodiment of the present disclosure, which is a schematic partial enlarged view of a position B in FIG. 19. As shown in FIG. 21, there is a second junction position Q2 between the second transition region 240 and the bonding pin region 250. Multiple fourth structure holes 61 of the second transition region 240 may be provided in an area of the second transition region 240 close to the second junction position Q2 with respect to the second junction position Q2.

In an exemplary implementation, the fourth structure hole 61 of the second transition region 240 may be provided in an area of the second transition region 240 close to the bonding pin region 250 and the fourth structure hole 61 may be provided in the inorganic insulation layer 14.

In an exemplary implementation, a metal line 15 covers a hole wall and a hole bottom of a fourth structure hole 61.

In an exemplary implementation, in a plane parallel to the base substrate, a shape of the first structure hole 61 may include any one or more of the following: a triangle, a rectangle, a pentagon, a hexagon, a circle, and an ellipse.

In an exemplary implementation, the third structure hole or the fourth structure hole may have a circular shape and have a diameter D.

In an exemplary implementation, the third structure hole or the fourth structure hole may have the same diameter in the first direction D1. That is, the third structure hole or the fourth structure hole may have the same area.

In an exemplary implementation, the third structure hole or the fourth structure hole may adopt a structure in which an area is gradually changed.

In an exemplary implementation, a diameter D of the third structure hole or the fourth structure hole may be greater than or equal to ¼ of a width W of the metal line and less than or equal to ⅔ of the width W of the metal line.

In an exemplary implementation, the third structure hole or the fourth structure hole has an elliptical shape, and has a major axis L1 extending in the second direction D2 and a minor axis L2 extending in the first direction D1.

In an exemplary implementation, the third structure hole or the fourth structure hole may adopt a structure in which an area of an ellipse is gradually changed.

In an exemplary implementation, the major axis L1 of the third structure hole or the fourth structure hole may be less than or equal to ⅔ of a width W of the metal line and the minor axis L2 may be greater than or equal to ¼ of the width W of the metal line

In an exemplary implementation, an inorganic insulation layer is stacked on a base substrate by a method similar to that shown in FIGS. 9 and 10 and multiple structure holes are formed in the inorganic insulation layer by a method similar to that shown in FIGS. 14A to 14E.

In an embodiment of the present disclosure, at least one structure hole is provided in an inorganic insulation layer in an area where the inorganic insulation layer is retained (such as the first transition region or the second transition region), so that when a metal line is formed by a patterning process, metal will be deposited into the structural hole of the inorganic insulation layer to form metal pits. When the photoresist is coated, because the photoresist will fill multiple metal pits, a friction force between the photoresist and a metal layer is increased, so that a flow of photoresist from the high position to the low position can further reduced or slow down, thereby avoiding the photoresist at the high position being too thin to cause the metal at the high position to be exposed and etched.

The structure of the display substrate and the manufacturing process thereof according to the exemplary embodiments of the present disclosure are described by way of example only. In an exemplary implementation, corresponding structures may be changed and patterning processes may be added or reduced according to actual needs, which are not limited in the present disclosure.

In an exemplary implementation, the display substrate of an embodiment of the present disclosure may be applied to a display apparatus with a pixel drive circuit, such as an OLED, a quantum dot display (QLED), a light emitting diode display (Micro LED or Mini LED) or a quantum dot light emitting diode display (QDLED), etc., which is not limited here in the present disclosure.

An embodiment of the present disclosure further provides a manufacturing method of a display substrate. The display substrate includes a display area and a bonding area located on a side of the display area, the bonding area includes a lead region, a first transition region, a bending region, a second transition region, and a bonding pin region sequentially provided in a direction away from the display area. The manufacturing method includes: forming a composite insulation layer provided on a base substrate and a metal line provided on a side of the composite insulation layer away from the base substrate in a lead region and a bonding pin area, and forming a composite insulation layer provided on the base substrate, an inorganic insulation layer provided on a side of the composite insulation layer away from the base substrate, and a metal line provided on a side of the inorganic insulation layer away from the base substrate in a first transition region and a second transition region. The bonding area is further formed with a structure hole maintaining photoresist thicknesses of the first transition region and the second transition region.

An embodiment of the present disclosure further provides a display apparatus which includes the display substrate in any of the aforementioned embodiments. The display apparatus may be any product or component with a display function, such as a mobile phone, a tablet computer, a television, a display, a laptop computer, a digital photo frame, or a navigator.

Although the implementations of the present disclosure are disclosed above, the contents are only implementations used for ease of understanding of the present disclosure, but not intended to limit the present disclosure. Any of those skilled in the art of the present disclosure can make any modifications and variations in the forms and details of implementation without departing from the spirit and scope of the present disclosure. However, the protection scope of the present disclosure should be subject to the scope defined by the appended claims.

1. A display substrate, comprising a display area and a bonding area located on a side of the display area,
wherein the bonding area comprises a lead region, a first transition region, a bending region, a second transition region, and a bonding pin region sequentially provided in a direction away from the display area; in a plane perpendicular to the display substrate, the lead region and the bonding pin region comprise a composite insulation layer provided on a base substrate and a metal line provided on a side of the composite insulation layer away from the base substrate, the first transition region and the second transition region comprise a composite insulation layer provided on the base substrate, an inorganic insulation layer provided on a side of the composite insulation layer away from the base substrate, and a metal line provided on a side of the inorganic insulation layer away from the base substrate; the bonding area is further provided with a structure hole for maintaining photoresist thicknesses of the first transition region and the second transition region.

2. The display substrate according to claim 1, wherein at least one structure hole is provided in at least one or more of the lead region, the first transition region, the second transition region, and the bonding pin region and the structure hole is provided in the metal line.

3. The display substrate according to claim 2, wherein the structure hole comprises a first structure hole and the first structure hole is provided at any one or more of the following positions: the lead region and the first transition region.

4. The display substrate according to claim 3, wherein the first structure hole of the lead region is provided in an area of the lead region close to the first transition region, and the first structure hole of the first transition region is provided in an area of the first transition region close to the lead region.

5. The display substrate according to claim 4, wherein the first transition region comprises a first climbing region and a first planarization region, the first climbing region is located on a side of the first transition region close to the lead region, the first planarization region is located on a side of the first climbing region away from the lead region, and the first structure hole is provided in a metal line of the first planarization region.

6. The display substrate according to claim 2, wherein the structure hole comprises a second structure hole and the second structure hole is provided at any one or more of the following positions: the bonding pin region and the second transition region.

7. The display substrate according to claim 6, wherein the second structure hole of the bonding pin region is provided in an area of the bonding pin region close to the second transition region and the second structure hole of the second transition region is provided in an area of the second transition region close to the bonding pin region.

8. The display substrate according to claim 7, wherein the second transition region comprises a second climbing region and a second planarization region, the second climbing region is located on a side of the second transition region close to the bonding pin region, the second planarization region is located on a side of the second climbing region away from the bonding pin region, and the second structure hole is provided in a metal line of the second planarization region.

9. The display substrate according to claim 1, wherein at least one structure hole is provided in at least one or more of the first transition region and the second transition region and the structure hole is provided in the inorganic insulation layer.

10. The display substrate according to claim 9, wherein the structure hole comprises a third structure hole and a fourth structure hole, the third structure hole is provided in the first transition region, and the fourth structure hole is provided in the second transition region.

11. The display substrate according to claim 10, wherein the third structure hole is provided in an area of the first transition region close to the lead region and the fourth structure hole is provided in an area of the second transition region close to the bonding pin region.

12. The display substrate according to claim 11, wherein the metal line covers a hole wall and a hole bottom of the third structure hole and the metal line covers a hole wall and a hole bottom of the fourth structure hole.

13. The display substrate according to claim 1, wherein a shape of the structure hole comprises any one or more of the following: a triangle, a rectangle, a pentagon, a hexagon, a circle, and an ellipse.

14. The display substrate according to claim 13, wherein the structure hole has a circular shape, a diameter of the structure hole is greater than or equal to ¼ of a width of the metal line, the diameter of the structure hole is less than or equal to ⅔ of the width of the metal line, and the width of the metal line is a dimension perpendicular to an extension direction of the metal line.

15. The display substrate according to claim 13, wherein a plurality of structure holes have the same area.

16. The display substrate according to claim 13, wherein an area of a plurality of structure holes is gradually increased in the direction away from the display area, or an area of the plurality of structure holes is gradually increased in a direction close to the display area.

17. The display substrate according to claim 16, wherein an area of a plurality of structure holes in the lead region is gradually increased in a direction away from the first transition region; an area of a plurality of structure holes in the first transition region is gradually increased in a direction away from the lead region; an area of a plurality of structure holes in the second transition region is gradually increased in a direction away from the bonding pin region; and an area of a plurality of structure holes in the bonding pin region is gradually increased in a direction away from the second transition region.

18. A display apparatus, comprising the display substrate according to claim 1.

19. A manufacturing method of a display substrate, wherein the display substrate comprises a display area and a bonding area located on a side of the display area and the bonding area comprises a lead region, a first transition region, a bending region, a second transition region, and a bonding pin region sequentially provided in a direction away from the display area;
the manufacturing method comprises:
forming a composite insulation layer provided on a base substrate and a metal line provided on a side of the composite insulation layer away from the base substrate in the lead region and the bonding pin region;
forming a composite insulation layer provided on the base substrate, an inorganic insulation layer provided on a side of the composite insulation layer away from the base substrate, and a metal line provided on a side of the inorganic insulation layer away from the base substrate in the first transition region and the second transition region; and
forming a structure hole for maintaining photoresist thicknesses of the first transition region and the second transition region in the bonding area.

20. The display substrate according to claim 2, wherein a shape of the structure hole comprises any one or more of the following: a triangle, a rectangle, a pentagon, a hexagon, a circle, and an ellipse.
